(19) United States
(12) Patent Application Publication
(10) Pub. No.: US 2025/0389017 A1
(43) Pub. Date: Dec. 25, 2025

(54) METHODS OF FORMING MAGNESIUM OXIDE LAYERS AND METHODS FOR FORMING MAGNESIUM INDIUM ZINC OXIDE LAYERS INCLUDING A MAGNESIUM OXIDE COMPONENT

(71) Applicant: ASM IP Holding B.V., Almere (NL)

(72) Inventors: Emre Yarali, Helsinki (FI); Aditya Chauhan, Ottignies-Louvain-la-Neuve (BE)

(21) Appl. No.: 19/244,405

(22) Filed: Jun. 20, 2025

Related U.S. Application Data
(60) Provisional application No. 63/662,200, filed on Jun. 20, 2024.

(51) Int. Cl. C23C 16/455; C23C 16/40; H01L 21/02

(52) U.S. Cl. CPC C23C 16/45531; C23C 16/40; C23C 16/403; C23C 16/45527; C23C 16/45553; H01L 21/02565; H01L 21/0262

(57) ABSTRACT

Methods for forming magnesium oxide layers are disclosed. The methods disclosed include performing cyclical deposition processes for forming magnesium oxide layers with a reduced or low carbon impurity concentration. Methods for forming magnesium indium zinc oxide layers including a magnesium oxide component with a reduced or low carbon impurity concentration are also disclosed.

### CROSS-REFERENCE TO RELATED APPLICATION(S)

This application claims the benefit of U.S. Provisional Application 63/662,200 filed on Jun. 20, 2024, the entire contents of which are incorporated herein by reference.

### FIELD

The present disclosure generally relates to the field of semiconductor processing methods, and to the field of device and integrated circuit manufacture. More particular, the present disclosure relates to cyclical deposition processes for forming magnesium oxide layers as well as for forming magnesium indium zinc oxide layers including a magnesium oxide component.

### BACKGROUND

Semiconducting oxides are increasingly being used in the semiconductor industry. For example, semiconducting oxides can be employed as the active layer in thin-film transistors (TFTs), as access transistors in 3D NAND/3D DRAM applications, and as the semiconductor layer in metal-semiconductor-metal (MSM) type photodetectors. However, the performance of devices and/or integrated circuits incorporating such semiconducting oxide materials may be negatively impacted by the materials impurity concentration, for example. Accordingly, improved semiconducting oxide materials and methods for forming such materials are desirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

Any discussion, including discussion of problems and solutions, set forth in this section, has been included in this disclosure solely for the purpose of providing a context for the present disclosure, and should not be taken as an admission that any or all of the discussion was known at the time the invention was made or otherwise constitutes prior art.

### BRIEF SUMMARY

This summary introduces a selection of concepts in a simplified form, which are described in further detail below. This summary is not intended to necessarily identify key features or essential features of the claimed subject matter, nor is it intended to be used to limit the scope of the claimed subject matter.

Various embodiments of the present disclosure relate to methods for forming magnesium oxide layers and magnesium indium zinc oxide layers including a magnesium oxide component by cyclical deposition processes.

According to one aspect a method for forming a magnesium oxide layer on a substrate disposed within a reaction chamber includes: performing a cyclical deposition process including a plurality of repeated deposition cycles, each deposition cycle including introducing an indium precursor into the reaction chamber thereby forming a plurality of indium species on a surface of the substrate; introducing a magnesium precursor into the reaction chamber wherein the magnesium precursor reacts with the plurality of indium species to form a reaction product on the surface of the substrate; and introducing an oxygen reactant into the reaction chamber wherein the oxygen reactant reacts with the reaction product forming magnesium oxide.

In one embodiment of the method, each deposition cycle further includes reintroducing the indium precursor into the reaction chamber after introducing the magnesium precursor and prior to introducing the oxygen reactant.

In one embodiment of the method, the indium precursor includes one or more of trimethylindium, triethylindium, ethyldimethylindium, and indium trichloride.

In one embodiment of the method, the magnesium precursor includes a ligand selected from a group consisting of cyclopentadienyl (Cp), beta-diketonate, amidinate, and diazadiene (DAD).

In one embodiment of the method, the magnesium precursor includes one or more of MgCp2, Mg(MeCp)2, Mg(EtCp)2, Mg(thd)2, Mg(acac)2, Mg(hfac)2, Mg(sBu2AMD)2, Mg(tBu2AMD)2, Mg(iPr2AMD)2, Mg(tPn2AMD)2, Mg(sBu2FMD)2, Mg(tBu2FMD)2, Mg(iPr2FMD)2, Mg(tPn2FMD)2, Mg(tBu2DAD)2, Mg(sBu2DAD)2, Mg(iPr2DAD)2, and Mg(tPn2DAD)2.

In one embodiment of the method, the magnesium oxide layer has a carbon content of less than 1 atomic percent (at-%).

According to another aspect a method of depositing a magnesium indium zinc oxide layer on a substrate disposed within a reaction chamber by a cyclical deposition process comprises: performing one or more magnesium oxide sub-cycles to deposit a magnesium oxide layer on the substrate, each magnesium oxide sub-cycle including: contacting the substrate with an indium precursor; contacting the substrate with a magnesium precursor; and contacting the substrate with an oxygen reactant. In such an aspect the method also includes performing one or more indium oxide sub-cycles to deposit an indium oxide layer on the substrate, each indium oxide sub-cycle including: contacting the substrate with the indium precursor; and contacting the substrate with the oxygen reactant. In such an aspect the method also includes performing one or more zinc oxide sub-cycles to deposit a zinc oxide layer on the substrate, each zinc oxide sub-cycle including: contacting the substrate with a zinc precursor; and contacting the substrate with the oxygen reactant.

In one embodiment of the method, the magnesium oxide sub-cycle further includes initially contacting the substrate with the indium precursor and subsequently contacting the substrate with the magnesium precursor.

In one embodiments of the method, after contacting the substrate with the magnesium precursor the magnesium oxide sub-cycle further includes contacting the substrate with the indium precursor for a second time.

In one embodiment of the method, the magnesium indium zinc oxide layer includes a mixture of a magnesium oxide, an indium oxide, and a zinc oxide.

In one embodiment of the method, the magnesium indium zinc oxide layer has a magnesium contact of less than 30 atomic percent (atomic-%).

In one embodiment of the method, the cyclical deposition process is performed at a deposition temperature of less than 250° C.

In one embodiment of the method, the oxygen reactant includes one or more of water, ozone, hydrogen peroxide, and an oxygen-based plasma.

In one embodiment of the method, the indium precursor includes one or more of trimethylindium, triethylindium, ethyldimethylindium, and indium trichloride.

In one embodiment of the method, the magnesium precursor includes a ligand selected from a group consisting of cyclopentadienyl (Cp), beta-diketonate, amidinate, and diazadiene (DAD).

In one embodiments of the method, the magnesium precursor includes one or more of MgCp2, Mg(MeCp)2, Mg(EtCp)2, Mg(thd)2, Mg(acac)2, Mg(hfac)2, Mg(sBu2AMD)2, Mg(tBu2AMD)2, Mg(iPr2AMD)2, Mg(tPn2AMD)2, Mg(sBu2FMD)2, Mg(tBu2FMD)2, Mg(iPr2FMD)2, Mg(tPn2FMD)2, Mg(tBu2DAD)2, Mg(sBu2DAD)2, Mg(iPr2DAD)2, and Mg(tPn2DAD)2.

According to another aspect a method of depositing a magnesium indium zinc oxide layer on a substrate disposed within a reaction chamber by a cyclical deposition process comprises: depositing a magnesium oxide layer on the substrate by an atomic layer deposition process comprising one or more deposition cycles, each magnesium oxide sub-cycle includes: contacting the substrate with an indium precursor; contacting the substrate with a magnesium precursor; and contacting the substrate with an oxygen reactant. In such an aspect the method also includes performing one or more indium zinc oxide sub-cycles to deposit an indium zinc oxide layer on the substrate, each indium zinc oxide sub-cycle comprising: contacting the substrate with the indium precursor; contacting the substrate with a zinc precursor; and contacting the substrate with the oxygen reactant.

In one embodiment of the method, the magnesium oxide sub-cycle further includes initially contacting the substrate with the indium precursor and subsequently contacting the substrate with the magnesium precursor.

In one embodiment of the method, after contacting the substrate with the magnesium precursor the magnesium oxide sub-cycle further includes contacting the substrate with the indium precursor for a second time.

In one embodiment of the method, after contacting the substrate with the magnesium precursor the magnesium oxide sub-cycle further comprises contacting the substrate with the indium precursor for a second time.

In one embodiment of the method, the magnesium indium zinc oxide layer comprises a mixture of a magnesium oxide and an indium zinc oxide.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a cyclical deposition process for forming a magnesium oxide layer on a substrate in accordance with one or more embodiments of the disclosure.

FIG. 2 illustrates a cyclical deposition process for forming a magnesium indium zinc oxide layer including a magnesium oxide component on a substrate in accordance with one or more embodiments of the disclosure.

FIG. 3 illustrates an additional cyclical deposition process for forming a magnesium indium zinc oxide layer including a magnesium oxide component on a substrate in accordance with one or more embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods and compositions provided below is merely exemplary and is intended for purposes of illustration only. The following description is not intended to limit the scope of the disclosure or the claims. Moreover, recitation of multiple embodiments having indicated features or steps is not intended to exclude other embodiments having additional features or steps or other embodiments incorporating different combinations of the stated features or steps.

As set forth in more detail below, various embodiments of the disclosure provide methods for forming magnesium oxide layers and magnesium indium zinc oxide layers (also referred to herein as MIZO layers). In various embodiments cyclical deposition processes are provided for forming magnesium oxide layers. In additional embodiments cyclical deposition processes are provided for forming magnesium indium zinc oxide layers including a magnesium oxide layer as a component of the MIZO layer. For example, magnesium indium zinc oxide layers may be formed by cyclical deposition processes which includes a magnesium oxide deposition stage, an indium oxide deposition stage, and a zinc oxide deposition stage, as described in detail below.

In various embodiments the cyclical deposition processes provided can form magnesium oxide layers having a low or reduced concentration of carbon impurities. In various additional embodiments the cyclical deposition processes provided can form magnesium indium zinc oxide layers including a magnesium oxide component having a low or reduced concentration of carbon impurities. A reduction in the concentration of carbon impurities in magnesium oxide layers and magnesium indium zinc oxide layers including a magnesium oxide component may improve the properties of the deposited layers. As a non-limiting example, a reduction in the concentration, or even the elimination of carbon impurities, in the magnesium oxide component of a magnesium indium zinc oxide layer may prevent the loss of zinc from the MIZO layer and/or the formation of metallic indium in the MIZO layer during layer formation and/or during post deposition processing of the MIZO layer.

In one aspect, methods for forming magnesium oxide layers with a low concentration of carbon impurities are provided. Such methods may comprise performing a cyclical deposition process comprising a plurality repeated deposition cycle. In some embodiments each deposition cycle can comprise the steps of (A) initially contacting the substrate with an indium precursor, (B) subsequently contacting the substrate with a magnesium precursor, (A) optionally contacting the substrate with the indium precursor for a second time and (C) contacting the substrate with an oxygen reactant.

In another aspect, methods for forming magnesium indium zinc oxide layers including a magnesium oxide component with a low concentration of carbon impurities are provided. Such methods may comprise performing a cyclical deposition process comprising a plurality repeated deposition cycle where a deposition cycle can comprise a super-cycle. In accordance with examples of the disclosure, a super-cycle can include one or more sub-cycles, each sub-cycle being employed for forming a component of the magnesium indium zinc oxide layer. The cyclical deposition processes of the present disclosure therefore allow for the controlled formation of MIZO layers with the desired material properties, such as, but not limited to, composition, thickness, stoichiometry, conductivity, impurity concentration, etc.

In this disclosure, gas can include material that is a gas at normal temperature and pressure (NTP), a vaporized solid and/or a vaporized liquid, and can be constituted by a single gas or a mixture of gases, depending on the context.

As used herein, the terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials and can include one or more layers overlying or underlying the bulk material. The substrate can include various topologies, such as gaps, including recesses, lines, trenches, or spaces between elevated portions, such as fins, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted.

As used herein, the term “layer” and/or “film” can used interchangeably and can refer to any continuous or non-continuous structure and material, such as material deposited by the methods disclosed herein. For example, a layer can include two-dimensional materials, three-dimensional materials, nanoparticles, partial or full molecular layers or partial or full atomic layers or clusters of atoms and/or molecules. A layer may partially or wholly consist of a plurality of dispersed atoms on a surface of a substrate and/or embedded in a substrate and/or embedded in a device manufactured on that substrate. A layer may comprise material or a layer with pinholes and/or isolated islands. A layer may be at least partially continuous. A layer may be patterned, e.g., subdivided, and may be comprised of a plurality of semiconductor devices.

As used herein, the term “cyclic deposition process” or “cyclical deposition process” can refer to the sequential introduction of precursors (and/or reactants) into a reaction chamber to deposit a layer over a substrate and includes processing techniques, such as atomic layer deposition (ALD), cyclical chemical vapor deposition (cyclical CVD), and hybrid cyclical deposition processes that include an ALD component and a cyclical CVD component. In some cases, a cyclical deposition process can include continually flowing one or more precursors, reactants, or inert gases, and pulsing other of the precursors or reactants.

As used herein, the term “atomic layer deposition” can refer to a vapor deposition process in which deposition cycles, typically a plurality of consecutive deposition cycles, are conducted in a process chamber. The term atomic layer deposition, as used herein, is also meant to include processes designated by related terms, such as chemical vapor atomic layer deposition, when performed with alternating pulses of precursor(s)/reactive gas(es), and purge (e.g., inert carrier) gas(es). Generally, for ALD processes, during each cycle, a precursor is introduced to a reaction chamber and is chemisorbed to a deposition surface (e.g., a substrate surface that can include a previously deposited material from a previous ALD cycle or other material), forming about a monolayer or sub-monolayer of material that does not readily react with additional precursor (i.e., a self-limiting reaction). Thereafter, in some cases, a reactant (e.g., another precursor or reaction gas) may subsequently be introduced into the process chamber for use in converting the chemisorbed precursor to the desired material on the deposition surface. The reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber.

As used herein, the term “purge” can refer to a procedure in which an inert or substantially inert gas is provided to a reaction chamber in between two pulses of gases that might otherwise react with each other. For example, a purge, e.g., using an inert gas, such as a noble gas, may be provided between a precursor pulse and a reactant pulse to reduce gas phase interactions between the precursor and the reactant that might otherwise occur. It shall be understood that a purge can be affected either in time or in space, or both. For example, in the case of temporal purges, a purge step can be used, e.g., in the temporal sequence of providing a precursor to a reaction chamber, providing a purge gas to the reaction chamber, and providing a reactant or another precursor to the reaction chamber, wherein the substrate on which a layer is deposited does not move. In the case of spatial purges, a purge step can take the following form: moving a substrate from a first location to which a precursor is (e.g., continually) supplied, through a purge gas curtain, to a second location to which a reactant or other precursor is (e.g., continually) supplied.

Further, in this disclosure, any two numbers of a variable can constitute a workable range of the variable, and any ranges indicated may include or exclude the endpoints. Additionally, any values of variables indicated (regardless of whether they are indicated with the term about or not) may refer to precise values or approximate values and include equivalents, and may refer to average, median, representative, majority, or the like. Further, in this disclosure, the terms including, constituted by and having refer independently to typically or broadly comprising, comprising, consisting essentially of, or consisting of in some embodiments.

In this disclosure, any defined meanings do not necessarily exclude ordinary and customary meanings, in some embodiments.

A number of example materials are given throughout the embodiments of the current disclosure, it should be noted that the chemical formulas given for each of the example materials should not be construed as limiting and that the non-limiting example materials given should not be limited by a given example stoichiometry.

In the specification, it will be understood that the term “on” or “over” may be used to describe a relative location relationship. Another element, film or layer may be directly on the mentioned layer, or another layer (an intermediate layer) or element may be intervened therebetween, or a layer may be disposed on a mentioned layer but not completely cover a surface of the mentioned layer. Therefore, unless the term “directly” is separately used, the term “on” or “over” will be construed to be a relative concept. Similarly, to this, it will be understood the term “under,” “underlying,” or “below” will be construed to be relative concepts.

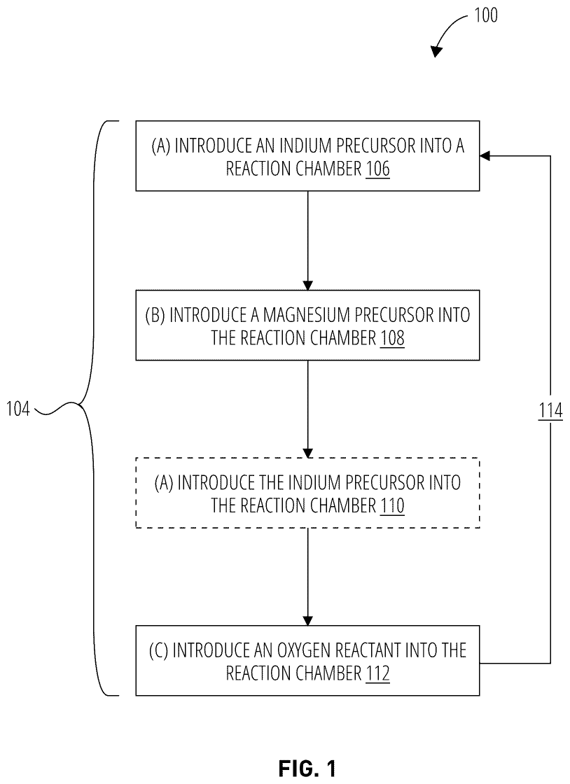

Turning now to the figures, FIG. 1 illustrates an exemplary cyclical deposition process 100 for forming a magnesium oxide layer on a substrate disposed within a reaction chamber.

In accordance with examples of the disclosure, the substrate on which deposition is desired, such as a semiconductor workpiece, is loaded into a reaction space of a reaction chamber. In some embodiments the reaction chamber can comprise a component or assembly of a single-wafer ALD reactor or a batch ALD reactor where deposition on multiple substrates takes place at the same time. In some embodiments the reaction chamber may form part of a cluster tool in which a variety of different processes for the fabrication of devices and/or integrated circuit are carried out. In some embodiments a flow-type reactor and associated reaction chamber can be utilized. In some embodiments a high-volume manufacturing-capable single wafer ALD reactor and associated reaction chamber can be used. In other embodiments a batch reactor comprising multiple substrates can be used. For embodiments in which batch ALD reactors are used, the number of substrates can be in the range of 10 to 200, in the range of 50 to 150, or in the range of 100 to 130.

The substrate disposed within the reaction chamber can be heated to a suitable substrate temperature (i.e., the deposition temperature), generally at reduced pressure. Deposition temperatures can be maintained below the precursor thermal decomposition temperature but at a high enough level to avoid condensation of reactants and to provide the activation energy for the desired surface reactions. Of course, the appropriate temperature window for any given ALD reaction will depend upon the surface termination and reactant species involved.

In some embodiments the deposition temperature (i.e., the substrate temperature) at which the magnesium oxide layer is formed on the substrate may be between 20° C. to 600° C., between 100° C. to 400° C., between 150° C. to 300° C., or between 200° C. to 250° C. In some embodiments the deposition temperature at which the magnesium oxide layer is formed on the substrate may be less than 600° C., less than 500° C., less than 400° C., less than 300° C., less than 250° C., less than 225° C., or less than 200° C. In some embodiments the deposition temperature is between 250° C. and 150° C.

Turning again to the cyclical deposition process 100 of FIG. 1, the process may further comprise performing a cyclical deposition process comprising a plurality of repeated deposition cycles 104, each deposition cycle 104 comprising: introducing an indium precursor into the reaction chamber (step 106), introducing a magnesium precursor into the reaction chamber (step 108), optionally reintroducing the indium precursor into the reaction chamber (optional step 110), and introducing an oxygen reactant into the reaction chamber (step 112). In various embodiments introducing the precursor/reactant (i.e., the indium precursor, the magnesium, and the oxygen reactant) can comprise pulsing the precursor/reactant into the reaction chamber wherein the precursor/reactant contacts the substrate disposed within the reaction chamber. For example, a pulse can comprise exposing a substrate to a precursor or reactant. This can be done, for example, by introducing a precursor or reactant to a reaction chamber in which the substrate is present. Additionally, or alternatively, exposing the substrate to a precursor can comprise moving the substrate to a location in a substrate processing system in which the reactant or precursor is present.

In accordance with examples of the disclosure, the indium precursor, the magnesium precursor, and the oxygen reactant can be purged from the reaction chamber—e.g., after each pulse of precursor/reactant and/or upon completion of steps 106, 108, optional step 110, and step 112 and/or after completion of a deposition cycle 104. In some embodiments the steps 106, 108, optional step 110, and step 112 can be repeated as illustrated by cycle loop 114. For example, the deposition cycle 104 can be performed 1 or more times, 2 or more times, 3 or more times, 5 or more times, 10 or more times, 25 or more times, or between 1 and 25 times. Further, steps 106, 108, optional step 110, and step 112 may be initiated and/or terminated in any order, or in a specific sequence. Yet further, each deposition cycle 104 can include multiple repetitions of steps 106, 108, optional step 110, and step 112 prior to proceeding to the subsequent step(s) of the deposition cycle 104. In some embodiments each deposition cycle 104 can also include one or more additional steps which can performed during each deposition cycle 104 or during select deposition cycles of the cyclical deposition process 100.

In accordance with examples of the disclosure, the steps of the deposition cycle 104 may be performed in a sequence to form a magnesium oxide layer having a low or reduced concentration of carbon impurities. In some embodiments, the deposition cycle 104 may comprise a sequence of steps including: introducing an indium precursor into the reaction chamber thereby forming a plurality of indium species on a surface of the substrate (step 106), introducing a magnesium precursor into the reaction chamber wherein the magnesium precursor reacts with the plurality of indium species to form a reaction product on the surface of the substrate (step 108), and introducing an oxygen reactant into the reaction chamber wherein the oxygen reactant reacts with the reaction product forming magnesium oxide (step 112).

In accordance with examples of the disclosure, the deposition cycle 104 may comprise (A) initially introducing the indium precursor into the reaction chamber (step 106) and (B) subsequently introducing the magnesium precursor into the reaction chamber (step 108). In such aspects, the deposition cycle 104 may also comprise (C) introducing the oxygen reactant into the reaction chamber (step 112) after the introduction of the magnesium precursor (step 108). In such examples the process steps of the deposition cycle 104 may be performed in a sequence given as [ABC] (i.e., step 106, followed by step 108, followed by step 112). In such examples, the deposition cycle 104 sequence [ABC] can be repeated one or more times, which may be written as [ABC]×N₁, where N₁ is a real integer, and the square brackets indicate one deposition cycle.

In accordance with additional examples of the disclosure, the deposition cycle 104 may comprise (A) initially introducing the indium precursor into the reaction chamber (step 106), (B) subsequently introducing the magnesium precursor into the reaction chamber (step 108), and (A) reintroducing the indium precursor into the reaction chamber (optional step 110) after introducing the magnesium precursor and prior to introducing the oxygen reactant. In such aspects, the deposition cycle 104 may also comprise (C) introducing the oxygen reactant into the reaction chamber (step 112) after the reintroduction of the indium precursor (optional step 110). In accordance with examples of the disclosure, the process steps of the deposition cycle 104 may be performed in a sequence given as [ABAC] (i.e., step 106, followed by step 108, followed by optional step 110, followed by step 112). In such examples, the deposition cycle 104 sequence [ABAC] can be repeated one or more times, which may be written as [ABAC]×N₂, where N₂ is a real integer, and the square brackets indicate one deposition cycle.

In some embodiments the indium precursor may comprise a metalorganic indium precursor. In such examples the metalorganic indium precursor may comprise a metalorganic compound having a low carbon content. In some embodiments the indium precursor comprises one or more of trimethylindium, triethylindium, ethyldimethylindium, and dimethylindium chloride.

In some embodiments, the indium precursor includes a ligand selected from a group consisting of an alkyl, an alkylamino, an alkoxy, a halide, a cyclopentadienyl (Cp), an alkoxide, an amide, an amidinate, a guanidinate, a beta-diketonate, and a triazenude. In such examples, the indium precursor may comprise one or more of trimethylindium, triethylindium, ethyldimethylindium, InMe2(CH2CH2CH2NMe2), InEt2(CH2CH2CH2NMe2), InMe2(CH2CH2CH2NEt2), InEt2(CH2CH2CH2NEt2), InMe2Cl, In(CpCH2CH2NMe2), In(CpCH2CH2CH2NMe2), InMe2(CpCH2CH2NMe2), InMe2(CpCH2CH2CH2NMe2), In(CpCH2CH₂OMe), In(CpCH2CH2CH₂OMe), InMe2(CpCH2CH₂OMe), InMe2(CpCH2CH2CH₂OMe, tris(tert-pentoxy)indium(III). tris(tert-butoxy)indium(III), In(dmamb)3. InMe2(dmap), tris(isopropoxy)indium(III), In(dmap)3, In(dmamp)3, InMe2(dmamp), InMe2(dmamb), InEt2(dmap), InEt2(dmamp), InEt2(dmamb), In(dmamp)2(OiPr), InMe2(NMe2), InMe2(NEt2), InMe2(NEtMe), InEt2(NMe2), InEt2(NEt2), InEt2(NEtMe), InMe2[N(SiMe3)2], InEt2[N(SiMe3)2], In(sBu2AMD)3, In(tBu2AMD)3, In(iPr2AMD)3, or In(tPn2AMD)3, In(tBu2FMD)3, In(iPr2FMD)3, In(tPn2FMD)3, In(thd)3, In(acac)3, In(hfac)3, and tris(di-tert-butyltriazenido)indium(III) In(sBu2FMD)3, and an indium precursor represented by InR2L, where R is a methyl or ethyl ligand and where L is selected from tBu2AMD, iPr2AMD, tPn2AMD, sBu2AMD, tBu2FMD, iPr2FMD, tPn2FMD, and sBu2FMD.

In some embodiments the indium precursor may comprise an inorganic indium precursor. In such embodiments the indium precursor may comprise an indium compound that does not contain carbon atoms, i.e., the indium precursor is a carbon-free indium precursor. In some embodiments the carbon-free indium precursor may comprise an indium halide compound. In such embodiments the indium precursor may comprise one or more of an indium chloride compound, an indium fluoride compound, an indium bromide compound, and an indium iodide compound. In some embodiments the indium precursor comprises an indium chloride compound. In such embodiments the indium precursor may comprise one or more of indium chloride (InCl), and indium trichloride (InCl₃).

In some embodiments the magnesium precursor may comprise a metalorganic magnesium precursor. In some embodiments the magnesium precursor may comprise a ligand selected from a group consisting of cyclopentadienyl (Cp), beta-diketonate, amidinate, and diazadiene (DAD). In such embodiments the magnesium precursor may comprise one or more of MgCp₂, Mg(MeCp)₂, Mg(EtCp)₂, Mg(thd)₂, Mg(acac)₂, Mg(hfac)₂, Mg(sBu₂AMD)₂, Mg(tBu₂AMD)₂, Mg(iPr₂AMD)₂, Mg(tPn₂AMD)₂, Mg(sBu₂FMD)₂, Mg(tBu₂FMD)₂, Mg(iPr₂FMD)₂, Mg(tPn₂FMD)₂, Mg(tBu₂DAD)₂, Mg(sBu₂DAD)₂, Mg(iPr₂DAD)₂, and Mg(tPn₂DAD)₂.

In some embodiments the oxygen reactant may comprise one or more of water (H₂O), ozone (O₃), and hydrogen peroxide (H₂O₂). In some embodiments the oxygen reactant may comprise an oxygen-based plasma generated from an oxygen containing gas.

In some embodiments the magnesium oxide layers formed have a carbon impurity concentration of less than 10 atomic-%, less than 5 atomic-%, less than 2 atomic-%, less than 1 atomic-%, less than 0.5 atomic-% or less than 0.1 atomic-%. In some embodiments the magnesium oxide layers formed have a hydrogen impurity concentration of less than 30 at-%, less than 20 at-%, less than 10 at-%, less than 5 at-%, less than 3 at-% or less than 1 at-%.

The various embodiments of the disclosure also provide methods for forming magnesium indium zinc oxide layers and particularly magnesium indium zinc oxide layers including a magnesium oxide component (e.g., a magnesium oxide layer). In some embodiments the methods provided may also comprise forming magnesium indium zinc oxide layers including a magnesium oxide component with a low concentration of carbon impurities. For example, such methods may comprise performing a cyclical deposition process comprising a plurality repeated deposition cycles where each deposition cycle can comprise a super-cycle. In accordance with examples of the disclosure a super-cycle can include one or more sub-cycles, each sub-cycle being employed for forming a component of the magnesium indium zinc oxide layer. The cyclical deposition processes of the present disclosure can therefore allow for the controlled formation of MIZO layers with the desired material properties, such as, but not limited to, composition, thickness, stoichiometry, conductivity, impurity concentration, etc.

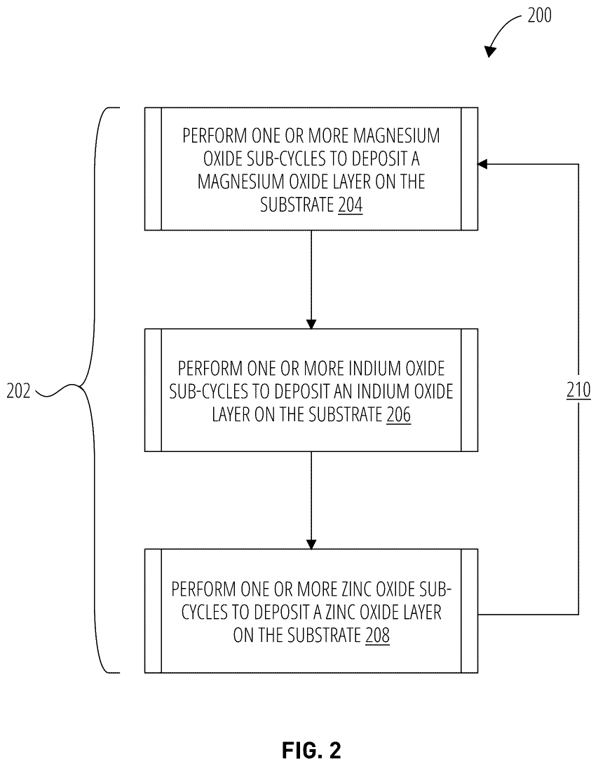

Turning again to the figures, FIG. 2 illustrates a cyclical deposition process 200 for forming a magnesium indium zinc oxide layer including a magnesium oxide component (e.g., a magnesium oxide layer) on a substrate in accordance with various embodiments. In accordance with examples of the disclosure, cyclical deposition process 200 may comprise seating a substrate within a reaction chamber and heating the substrate to a suitable deposition temperature, as previously described with reference to the cyclical deposition process 100 of FIG. 1.

In accordance with examples of the disclosure, cyclical deposition process 200 may comprise performing a cyclical deposition process comprising a plurality of repeated deposition super-cycles 202. In such examples each deposition super-cycle 202 may comprise: performing one or more magnesium oxide sub-cycles to deposit a magnesium oxide layer on the substrate (sub-cycle 204), performing one or more indium oxide sub-cycles to deposit an indium oxide layer on the substrate (sub-cycle 206), and performing one or more zinc oxide sub-cycles to deposit a zinc oxide layer on the substrate (sub-cycle 208).

In accordance with examples of the disclosure, the reaction chamber may be purged while performing each sub-cycle 204, 206, and 208, e.g., after each pulse of precursor/reactant and/or upon completion of sub-cycles 204, 206, and 208, and/or after completion of a deposition super-cycle 202. In some embodiments the sub-cycles 204, 206, and 208 can be repeated as illustrated by super-cycle loop 210. For example, the deposition super-cycle 202 can be performed 1 or more times, 2 or more times, 3 or more times, 5 or more times, 10 or more times, 25 or more times, or between 1 and 25 times. Further, sub-cycle 204, sub-cycle 206, and sub-cycle 208 may be initiated and/or terminated in any order, or in a specific sequence. Yet further, each deposition super-cycle 202 can include multiple repetitions of sub-cycle 204, sub-cycle 206, and sub-cycle 208 prior to proceeding to the subsequent sub-cycle(s) of the deposition super-cycle 202. In some embodiments each deposition super-cycle 202 can also include one or more additional steps and/or sub-cycles which can performed during each deposition super-cycle 202 or during select deposition super-cycle 202 of the cyclical deposition process 200.

Turning now to the individual sub-cycles of cyclical deposition process 200, i.e., the magnesium oxide sub-cycle 204, the indium oxide sub-cycle 206, and the zinc oxide sub-cycle 208.

In accordance with examples of the disclosure, the magnesium oxide sub-cycle 204 can be performed one or more times to deposit a magnesium oxide layer on the substrate, the magnesium oxide layer comprising the magnesium oxide component of the magnesium indium zinc oxide layer. In some embodiments the constituent process steps comprising the magnesium oxide sub-cycle 204 can be the same, or substantially the same, to those previously described with reference to cyclical deposition process 100.

In one aspect, the magnesium oxide sub-cycle 204 may comprise (A) initially contacting the substrate with the indium precursor and (B) subsequently contacting the substrate with the magnesium precursor. In such aspects the magnesium oxide sub-cycle 204 may also comprise (C) contacting the substrate with the oxygen reactant after the introduction of the magnesium precursor. In accordance with examples of the disclosure, the process steps of the magnesium oxide sub-cycle 204 may be performed in a sequence given as [ABC] where (A) comprises the process step of contacting the substrate with the indium precursor into, (B) comprises the process step of contacting the substrate with the magnesium precursor, and (C) comprises the process step of contacting the substrate with the oxygen reactant. In such examples the magnesium oxide sub-cycle 204 sequence [ABC] can be repeated one or more times, which may be written as [ABC]×N₃, where N₃ is a real integer, and the square brackets indicate one sub-cycle of the magnesium oxide sub-cycle 204.

In another aspect, the magnesium oxide sub-cycle 204 may comprise (A) initially contacting the substrate with the indium precursor, (B) subsequently contacting the substrate with the magnesium precursor, and (A) reintroducing the indium precursor into the reaction chamber and contacting the substrate with the indium precursor after introducing the magnesium precursor and prior to introducing the oxygen reactant. In such aspects, the magnesium oxide sub-cycle 204 may also comprise (C) introducing the oxygen reactant into the reaction chamber after the reintroduction of the indium precursor. In accordance with examples of the disclosure, the process steps of the magnesium oxide sub-cycle 204 may be performed in a sequence given as [ABAC] where (A) comprises the process step of contacting the substrate with the indium precursor into, (B) comprises the process step of contacting the substrate with the magnesium precursor, and (C) comprises the process step of contacting the substrate with the oxygen reactant. In such examples, the magnesium oxide sub-cycle 204 sequence [ABAC] can be repeated one or more times, which may be written as [ABAC]×N₄, where N₄ is a real integer, and the square brackets indicate sub-cycle of the magnesium oxide sub-cycle 204.

In accordance with examples of the disclosure, the cyclical deposition process 200 (FIG. 2) may also include an indium oxide sub-cycle 206. In such examples, the indium oxide sub-cycle 206 can be performed one or more times to deposit an indium oxide layer on the substrate, the indium oxide layer comprising the indium oxide component of the magnesium indium zinc oxide layer. In some embodiment the indium oxide sub-cycle 206 may comprise, (D) contacting the substrate with an indium precursor and (E) contacting the substrate with an oxygen reactant.

In accordance with examples of the disclosure, the reaction chamber may be purged after each pulse of precursor and reactant and/or upon completion of the indium oxide sub-cycle 206. In some embodiments, the indium oxide sub-cycle 206 can be repeated as desired to deposit an indium oxide layer of a desired thickness. For example, the indium oxide sub-cycle 206 can be performed 1 or more times, 2 or more times, 3 or more times, 5 or more times, 10 or more times, 25 or more times, or between 1 and 25 times. Further, the process steps of (D) contacting the substrate with the indium precursor, and (E) contacting the substrate with the oxygen reactant, may be initiated and/or terminated in any order, or in a specific sequence. Yet further, the indium oxide sub-cycle 206 can include multiple repetitions of (D) contacting the substrate with the indium precursor, and (E) contacting the substrate with the oxygen reactant, prior to proceeding to the subsequent process steps of the indium oxide sub-cycle 206. In some embodiments each indium oxide sub-cycle 206 can also include one or more additional steps which can performed during each indium oxide sub-cycle or during select indium oxide sub-cycles 206 of the cyclical deposition process 200.

In accordance with examples of the disclosure, the indium precursor utilized when performing the indium oxide sub-cycle 206 may be one or more of the indium compounds previously described with reference to the cyclical deposition process 100 (e.g., step 106). In one aspect the indium precursor employed when performing the indium oxide sub-cycle 206 may be the same as the indium precursor employed when performing the magnesium oxide sub-cycle 204.

In accordance with examples of the disclosure, the oxygen reactant utilized when performing the indium oxide sub-cycle 206 may be one or more of the oxygen reactants previously described with reference to the cyclical deposition process 100 (e.g., step 106). In one aspect the oxygen reactant employed when performing the indium oxide sub-cycle 206 may be the same as the oxygen reactant employed when performing the magnesium oxide sub-cycle 204.

In accordance with examples of the disclosure, the cyclical deposition process 200 (FIG. 2) may also include a zinc oxide sub-cycle 208. In such examples, the zinc oxide sub-cycle 208 can be performed one or more times to deposit a zinc oxide layer on the substrate, the zinc oxide layer comprising the zinc oxide component of the magnesium indium zinc oxide layer. In some embodiments the zinc oxide sub-cycle 208 may comprise, (F) contacting the substrate with a zinc precursor and (G) contacting the substrate with an oxygen reactant.

In accordance with examples of the disclosure, the reaction chamber may be purged after each pulse of precursor and reactant and/or upon completion of the zinc oxide sub-cycle 208. In some embodiments, the zinc oxide sub-cycle 208 can be repeated as desired to deposit a zinc oxide layer of a desired thickness. For example, the zinc oxide sub-cycle 208 can be performed 1 or more times, 2 or more times, 3 or more times, 5 or more times, 10 or more times, 25 or more times, or between 1 and 25 times. Further, the process steps of (F) contacting the substrate with the zinc precursor, and (G) contacting the substrate with the oxygen reactant, may be initiated and/or terminated in any order, or in a specific sequence. Yet further, the zinc oxide sub-cycle 208 can include multiple repetitions of (F) contacting the substrate with the zinc precursor, and (G) contacting the substrate with the oxygen reactant, prior to proceeding to the subsequent process steps of the zinc oxide sub-cycle 208. In some embodiments each zinc oxide sub-cycle 208 can also include one or more additional steps which can performed during each zinc oxide sub-cycle or during select zinc oxide sub-cycles 208 of the cyclical deposition process 200.

In accordance with examples of the disclosure, the zinc precursor may comprise a zinc compound including a ligand selected from a group consisting of an alkyl, an alkylamino, an alkoxy, a halide, a cyclopentadienyl (Cp), an alkoxide, an aminoalkoxide, an amide, a carboxylate, and a ketoiminate. In such examples the zinc precursor may comprise one or more of dimethylzinc, diethylzinc, bis[3-(N,N-dimethylamino)propyl]zinc, bis[3-(methoxy)propyl]zinc, bis[3-(ethoxy)propyl]zinc, ZnCl₂, ZnBr₂, ZnI₂, Zn(thd)₂, Zn(acac)₂, Zn(hfac)₂, Zn(dmap)₂, Zn(dmamp)₂, Zn(dmamb)₂, Zn(dab)₂, Zn(damb)₂, Zn(damp)₂, Zn(dadb)₂, ZnMe(OiPr), bis(trimethylsilylamido)zinc, zinc acetate, bis(N-(3′-dimethylaminopropyl)-2-penten-2-on-4-iminate) zinc(II), bis(N-(3′-dimethylaminoethyl)-2-penten-2-on-4-iminate) zinc(II), bis(N-(3′-ethoxypropyl)-2-penten-2-on-4-iminate) zinc(II), bis(N-(2′-ethoxyethyl)-2-penten-2-on-4-iminate) zinc(II), bis(N-(3′-methoxypropyl)-2-penten-2-on-4-iminate) zinc(II), bis(N-(2′-methoxyethyl)-2-penten-2-on-4-iminate) zinc(II), and bis(N-(n-propyl)-2-penten-2-on-4-iminate) zinc(II).

In accordance with examples of the disclosure, the oxygen reactant utilized when performing the zinc oxide sub-cycle 208 may be one or more of the oxygen reactants previously described with reference to the cyclical deposition process 100 (e.g., step 106). In one aspect the oxygen reactant employed when performing the zinc oxide sub-cycle 208 may be the same as the oxygen reactant employed when performing the magnesium oxide sub-cycle 204 and/or the same as the oxygen reactant employed when performing the indium oxide sub-cycle 206.

In some embodiments the magnesium indium zinc oxide layer deposited by cyclical deposition process 200 may comprise a mixture of one or more individual oxides, such as a magnesium oxide, an indium oxide, and a zinc oxide.

In one aspect the MIZO layer may comprise a discernable laminate structure comprising a repeated unit layer structure. In such embodiments performing one complete super-cycle may form a single unit layer structure. For example, each unit layer structure may be written as {(magnesium oxide)(indium oxide)(zinc oxide)} where the curly brackets denote a single unit layer structure. In some embodiments repeating the deposition super-cycle one or more times forms a layer of repeated unit layer structures which may be written as {(magnesium oxide)(indium oxide)(zinc oxide)}×N₅, where N₅ is a real integer. In such examples the laminate structure comprising the MIZO layer may be discernable by observation of the MIZO layer employing high magnification imaging techniques, such as, transmission electron microscopy, for example.

In another aspect the MIZO layer may comprise a mixture of the component oxides which are not discernable as a laminate structure. For example, the thickness of the individual oxide components and/or the deposition processes employed in forming the individual component oxides may result in a MIZO layer without discernable individual component layers.

In some embodiments the stoichiometry of the magnesium indium zinc oxide layer may be tuned by adjusting the ratio of the individual oxides in the layer. In some embodiments a desired stoichiometry of a magnesium indium zinc oxide layer may be achieved by selecting the number of times each sub-cycle (e.g., sub-cycles 204, 206, and 208) are repeated within a deposition super-cycle, for example to provide a desired Mg/In/Zn ratio. In some embodiments one or more magnesium oxide, indium oxide, and zinc oxide sub-cycles may be included in a deposition process to arrive at a desired magnesium, indium, and zinc content in a layer, such as a desired Mg/In/Zn ratio.

In some embodiments an additional reactant is included in one or more super-cycles. The additional reactant may, for example, improve the desired electrical properties of the magnesium indium zinc oxide layer. In some embodiments the additional reactant may be used to control the carrier density or concentration. In some embodiments the additional reactant may be used to control defect formation during deposition of the magnesium indium zinc oxide layer. In some embodiments the additional reactant may passivate oxygen vacancies in the growing magnesium indium zinc oxide layer. In some embodiments the additional reactant may comprise one or more of NH₃, N₂O, NO₂ and H₂O₂.

In some embodiments a MIZO layer is deposited to a thickness of 200 nm or less, about 100 nm or less, about 50 nm or less, about 30 nm or less, about 20 nm or less, about 10 nm or less, about 5 nm or less or about 3 nm or less. The MIZO layer will comprise at least the material deposited in one deposition cycle.

Cyclical deposition processes allow for conformal deposition of MIZO layers. In some embodiments the MIZO layers are deposited on a three-dimensional structure and the MIZO layers have at least 90%, 95% or higher conformality. In some embodiments the MIZO layers are about 100% conformal. In some embodiments the MIZO layers formed have a step coverage of more than 80%, more than 90%, or more than 95% in structures which have high aspect ratios. In some embodiments high aspect ratio structures have an aspect ratio that is more than 3:1 when comparing the depth/height to the width of the feature. In some embodiments the structures have an aspect ratio of more than 5:1, of more than 10:1, of more than 20:1, of more than 40:1, of more than 60:1, of more than 80:1, of more than 100:1, of more than 150:1, or an aspect ratio of 200:1 or greater.

In some embodiments the MIZO layers formed have a carbon impurity concentration of less than 10 atomic-%, less than 5 atomic-%, less than 2 atomic-%, less than 1 atomic-%, less than 0.5 atomic-%, or less than 0.1 atomic-%. In some embodiments the magnesium oxide layer formed have a hydrogen impurity concentration of less than 30 at-%, less than 20 at-%, less than 10 at-%, less than 5 at-%, less than 3 at-% or less than 1 at-%.

In some embodiments, the deposited MIZO layers have a stoichiometry or elemental ratio (In:Mg:Zn) of about 1:1:1, or from 0.1:1:1 to 10:1:1, or from 1:0.1:1 to 1:10:1, or from 1:1:0.1 to 1:1:10, or from 0.1:0.1:1 to 10:10:1, or from 0.1:1:0.1 to 10:1:10, or from 1:0.1:0.1 to 1:10:10. In some embodiments the MIZO layers formed have a stoichiometry or elemental ratio (In:Mg:Zn) from 0.01:1:1 to 100:1:1, or from 1:0.01:1 to 1:100:1, or from 1:1:0.01 to 1:1:100, or from 0.01:0.01:1 to 100:100:1, or from 0.01:1:0.01 to 100:1:100, or from 1:0.01:0.01 to 1:100:100.

In some embodiments the MIZO layers formed have an indium content (at-%) of less than 80 at-%, less than 70 at-%, less than 60 at-%, less than 50 at-%, less than 40 at-%, less than 30 at-%, less than 20 at-%, or less than 10 at-%. In some embodiments the MIZO layers formed have an indium content (at-%) between 80 at-% and 10 at-%, between 70 at-% and 20 at-%, or between 60 at-% and 30 at-%.

In some embodiments the MIZO layers formed have a magnesium content (at-%) of less than 80 at-%, less than 70 at-%, less than 60 at-%, less than 50 at-%, less than 40 at-%, less than 30 at-%, less than 20 at-%, or less than 10 at-%. In some embodiments the MIZO layers formed have a magnesium content (at-%) between 80 at-% and 10 at-%, between 70 at-% and 20 atom-%, or between 60 atom-% and 30 at-%.

In some embodiments the MIZO layers formed have a zinc content (at-%) of less than 40 at-%, less than 30 at-%, less than 20 at-%, less than 15 at-%, less than 10 at-%, or less than 5 at-%. In some embodiments the MIZO layers formed have a zinc content (at-%) between 40 at-% and 5 at-%, between 30 at-% and 10 at-%, or between 20 at-% and 15 at-%.

In some embodiments the MIZO layers formed have a thickness non-uniformity of less than 10%, less than 5%, less than 2%, less than 1% or less than 0.5% (1 sigma standard deviation) in 200- or 300-mm wafers or other substrates like square substrates.

In some embodiments the MIZO layers formed have an elemental compositional non-uniformity (metal atom concentration non-uniformity) across the direction of the substrate surface of less than 30%, less than 20%, less than 10%, less than 5%, less than 2%, less than 1% or less than 0.5% (1 sigma standard deviation) in 200 or 300 mm wafers or other substrates like square substrates.

The various embodiments of the disclosure also provide additional methods for forming magnesium indium zinc oxide layers and particularly magnesium indium zinc oxide layers including a magnesium oxide component (e.g., a magnesium oxide layer) and an indium zinc oxide component.

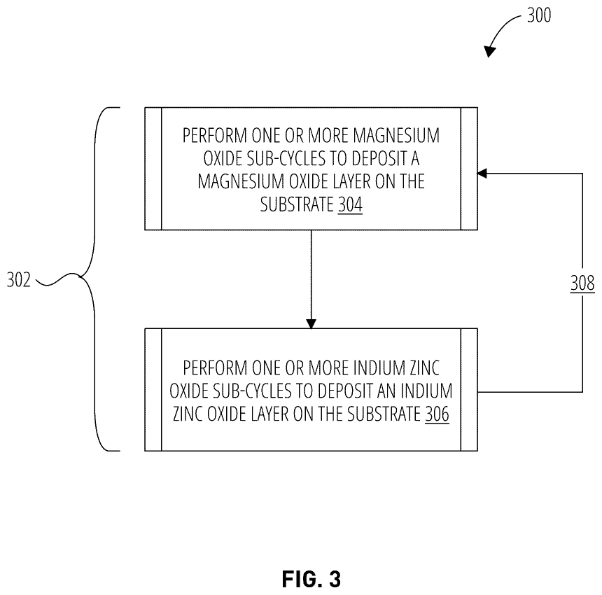

Turning again to the figures, FIG. 3 illustrates a cyclical deposition process 300 for forming a magnesium indium zinc oxide layer including a magnesium oxide component (e.g., a magnesium oxide layer) on a substrate in accordance with various embodiments. The cyclical deposition process 300 of FIG. 3 may comprise seating a substrate within a reaction chamber and heating the substrate to a suitable deposition temperature, as previously described with reference to the cyclical deposition process 100 of FIG. 1.

In accordance with examples of the disclosure, cyclical deposition process 300 may comprise performing a cyclical deposition process comprising a plurality of repeated deposition super-cycles 302. In such examples each deposition super-cycle 302 may comprise: performing one or more magnesium oxide sub-cycles to deposit a magnesium oxide layer on the substrate (sub-cycle 304) and performing one or more indium zinc oxide sub-cycles to deposit an indium zinc oxide layer on the substrate (sub-cycle 306).

In accordance with examples of the disclosure, the reaction chamber may be purged while performing each sub-cycle (304, and 306)—e.g., after each pulse of precursor/reactant and/or upon completion of sub-cycles 304 and 306 and/or after completion of a deposition super-cycle 302. In some embodiments, the sub-cycles 304 and 306 can be repeated as illustrated by super-cycle loop 308. For example, the deposition super-cycle 302 can be performed 1 or more times, 2 or more times, 3 or more times, 5 or more times, 10 or more times, 25 or more times, or between 1 and 25 times. Further, sub-cycle 304, and sub-cycle 306 may be initiated and/or terminated in any order, or in a specific sequence. Yet further, each deposition super-cycle 302 can include multiple repetitions of sub-cycle 304 and sub-cycle 306 prior to proceeding to the subsequent sub-cycle(s) of the deposition super-cycle 302. In some embodiments, each deposition super-cycle 302 can also include one or more additional steps and/or sub-cycles which can performed during each deposition super-cycle 302 or during select deposition super-cycle 302 of the cyclical deposition process 300.

Turning now to the individual sub-cycles of cyclical deposition process 300, i.e., the magnesium oxide sub-cycle 304 and the indium zinc oxide sub-cycle 306.

In accordance with examples of the disclosure, the magnesium oxide sub-cycle 304 can be performed one or more times to deposit a magnesium oxide layer on the substrate, the magnesium oxide layer comprising the magnesium oxide component of the magnesium indium zinc oxide layer. In some embodiments the constituent process steps comprising the magnesium oxide sub-cycle 304 can be the same, or substantially the same, to those previously described with reference to cyclical deposition process 200 and particular to sub-cycle 204 and are not repeated here.

In accordance with examples of the disclosure, the cyclical deposition process 300 (FIG. 3) may also include an indium zinc oxide sub-cycle 306. In such examples the indium zinc oxide sub-cycle 306 can be performed one or more times to deposit an indium zinc oxide layer on the substrate, the indium zinc oxide layer comprising the indium zinc oxide component of the magnesium indium zinc oxide layer. In some embodiments the indium zinc oxide sub-cycle 306 may comprise, (H) contacting the substrate with an indium precursor, (I) contacting the substrate with a zinc precursor, and (J) contacting the substrate with an oxygen reactant.

In accordance with examples of the disclosure, the reaction chamber may be purged after each pulse of precursor and reactant and/or upon completion of the indium zinc oxide sub-cycle 306. In some embodiments the indium zinc oxide sub-cycle 306 can be repeated as desired to deposit an indium zinc oxide layer of a desired thickness. For example, the indium zinc oxide sub-cycle 306 can be performed 1 or more times, 2 or more times, 3 or more times, 5 or more times, 10 or more times, 25 or more times, or between 1 and 25 times. Further, the process steps of (H) contacting the substrate with the indium precursor, (I) contacting the substrate with a zinc precursor, and (J) contacting the substrate with an oxygen reactant, may be initiated and/or terminated in any order, or in a specific sequence. Yet further, the indium zinc oxide sub-cycle 306 can include multiple repetitions of (H) contacting the substrate with the indium precursor, and (I) contacting the substrate with a zinc precursor, and (J) contacting the substrate with the oxygen reactant, prior to proceeding to the subsequent process steps of the indium zinc oxide sub-cycle 306. In some embodiments each indium zinc oxide sub-cycle 306 can also include one or more additional steps which can performed during each indium zinc oxide sub-cycle 306 or during select indium zinc oxide sub-cycle 306 of the cyclical deposition process 300.

In accordance with examples of the disclosure, the indium precursor, zinc precursor, and oxygen reactant utilized when performing the indium zinc oxide sub-cycle 306 may be one or more of the compounds previously described with reference to the cyclical deposition process 100 and the cyclical deposition process 200.

In some embodiments the magnesium indium zinc oxide layer deposited by cyclical deposition process 200 may comprise a mixture of one or more individual oxides, such as a magnesium oxide and an indium zinc oxide. In some embodiments the MIZO layer may comprise a discernable laminate structure comprising a repeated unit layer structure, as previously described. For example, each unit layer structure may be written as {(magnesium oxide)(indium zinc oxide)} where the curly brackets denote a single unit layer structure formed by executing the deposition super-cycle 302 a single time. In some embodiments repeating the deposition super-cycle 302 one or more times forms a layer of repeated unit layer structures which may be written as {(magnesium oxide)(indium zinc oxide)}×N₆, where N₆ is a real integer. In alternative embodiment a MIZO layer formed by the cyclical deposition process 300 may result in a MIZO without a discernable laminate structure, as previously described.

In some embodiments the stoichiometry of a magnesium indium zinc oxide layer formed by cyclical deposition process 300 of FIG. 3 may be tuned by adjusting the ratio of the individual oxides in the layer. In some embodiments a desired stoichiometry of a magnesium indium zinc oxide layer may be achieved by selecting the number of times each sub-cycle (e.g., sub-cycle 304 and sub-cycle 306) are repeated within a deposition super-cycle 302, for example to provide a desired Mg/InZn ratio. In some embodiments one or more magnesium oxide and indium zinc oxide sub-cycles may be included in a deposition process to arrive at a desired magnesium, indium, and zinc content in a layer, such as a desired Mg/InZn ratio.

For purposes of summarizing the invention and the advantages achieved over the prior art, certain objects and advantages of the invention have been described herein above. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught or suggested herein without necessarily achieving other objects or advantages as may be taught or suggested herein.

All of these embodiments are intended to be within the scope of the invention herein disclosed. These and other embodiments will become readily apparent to those skilled in the art from the following detailed description of certain embodiments having reference to the attached figures, the invention not being limited to any particular embodiment(s) disclosed.

What is claimed is:

1. A method for forming a magnesium oxide layer on a substrate disposed within a reaction chamber, the method comprising:
performing a cyclical deposition process comprising a plurality of repeated deposition cycles, each deposition cycle comprising:
introducing an indium precursor into the reaction chamber thereby forming a plurality of indium species on a surface of the substrate;
introducing a magnesium precursor into the reaction chamber wherein the magnesium precursor reacts with the plurality of indium species to form a reaction product on the surface of the substrate; and
introducing an oxygen reactant into the reaction chamber wherein the oxygen reactant reacts with the reaction product forming magnesium oxide.

2. The method of claim 1, wherein each deposition cycle further comprises reintroducing the indium precursor into the reaction chamber after introducing the magnesium precursor and prior to introducing the oxygen reactant.

3. The method of claim 1, wherein the indium precursor comprises one or more of trimethylindium, triethylindium, ethyldimethylindium, and indium trichloride.

4. The method of claim 1, wherein the magnesium precursor comprises a ligand selected from a group consisting of cyclopentadienyl (Cp), beta-diketonate, amidinate, and diazadiene (DAD).

5. The method of claim 4, wherein the magnesium precursor comprises one or more of MgCp2, Mg(MeCp)2, Mg(EtCp)2, Mg(thd)2, Mg(acac)2, Mg(hfac)2, Mg(sBu2AMD)2, Mg(tBu2AMD)2, Mg(iPr2AMD)2, Mg(tPn2AMD)2, Mg(sBu2FMD)2, Mg(tBu2FMD)2, Mg(iPr2FMD)2, Mg(tPn2FMD)2, Mg(tBu2DAD)2, Mg(sBu2DAD)2, Mg(iPr2DAD)2, and Mg(tPn2DAD)2.

6. The method of claim 1, wherein the magnesium oxide layer has a carbon content of less than 1 atomic percent.

7. A method of depositing a magnesium indium zinc oxide layer on a substrate disposed within a reaction chamber by a cyclical deposition process, the method comprising:
performing one or more magnesium oxide sub-cycles to deposit a magnesium oxide layer on the substrate, each of the one or more magnesium oxide sub-cycle comprising:
contacting the substrate with an indium precursor;
contacting the substrate with a magnesium precursor; and
contacting the substrate with an oxygen reactant;
performing one or more indium oxide sub-cycles to deposit an indium oxide layer on the substrate, each of the one or more indium oxide sub-cycle comprising:
contacting the substrate with the indium precursor; and
contacting the substrate with the oxygen reactant; and
performing one or more zinc oxide sub-cycles to deposit a zinc oxide layer on the substrate, each of the one or more zinc oxide sub-cycle comprising:
contacting the substrate with a zinc precursor; and
contacting the substrate with the oxygen reactant.

8. The method of claim 7, wherein the magnesium oxide sub-cycle further comprises initially contacting the substrate with the indium precursor and subsequently contacting the substrate with the magnesium precursor.

9. The method of claim 8, wherein after contacting the substrate with the magnesium precursor the magnesium oxide sub-cycle further comprises contacting the substrate with the indium precursor for a second time.

10. The method of claim 7, wherein the magnesium indium zinc oxide layer comprises a mixture of a magnesium oxide, an indium oxide, and a zinc oxide.

11. The method of claim 10, wherein the magnesium indium zinc oxide layer has a magnesium contact of less than 30 atomic percent.

12. The method of claim 7, wherein the cyclical deposition process is performed at a deposition temperature of less than 250° C.

13. The method of claim 7, wherein the oxygen reactant comprises one or more of water, ozone, and hydrogen peroxide.

14. The method of claim 7, wherein the indium precursor comprises one or more of trimethylindium, triethylindium, ethyldimethylindium, and indium trichloride.

15. The method of claim 7, wherein the magnesium precursor comprises a ligand selected from a group consisting of cyclopentadienyl (Cp), beta-diketonate, amidinate, and diazadiene (DAD).

16. The method of claim 15, wherein the magnesium precursor comprises one or more of MgCp2, Mg(MeCp)2, Mg(EtCp)2, Mg(thd)2, Mg(acac)2, Mg(hfac)2, Mg(sBu2AMD)2, Mg(tBu2AMD)2, Mg(iPr2AMD)2, Mg(tPn2AMD)2, Mg(sBu2FMD)2, Mg(tBu2FMD)2, Mg(iPr2FMD)2, Mg(tPn2FMD)2, Mg(tBu2DAD)2, Mg(sBu2DAD)2, Mg(iPr2DAD)2, and Mg(tPn2DAD)2.

17. A method of depositing a magnesium indium zinc oxide layer on a substrate disposed within a reaction chamber by a cyclical deposition process, the method comprising:
depositing a magnesium oxide layer on the substrate by an atomic layer deposition process comprising one or more magnesium oxide sub-cycles, each magnesium oxide sub-cycle comprising:
contacting the substrate with an indium precursor;
contacting the substrate with a magnesium precursor; and
contacting the substrate with an oxygen reactant;
performing one or more indium zinc oxide sub-cycles to deposit an indium zinc oxide layer on the substrate, each indium zinc oxide sub-cycle comprising:
contacting the substrate with the indium precursor; and
contacting the substrate with a zinc precursor; and
contacting the substrate with the oxygen reactant.

18. The method of claim 17, wherein the magnesium oxide sub-cycle further comprises initially contacting the substrate with the indium precursor and subsequently contacting the substrate with the magnesium precursor.

19. The method of claim 18, wherein after contacting the substrate with the magnesium precursor the magnesium oxide sub-cycle further comprises contacting the substrate with the indium precursor for a second time.

20. The method of claim 17, wherein the magnesium indium zinc oxide layer comprises a mixture of a magnesium oxide and an indium zinc oxide.
